(19) United States
(12) Patent Application Publication
(10) Pub. No.: US 2013/0146120 A1
(43) Pub. Date: Jun. 13, 2013

(54) HIGH CONCENTRATION PHOTOVOLTAIC MODULES AND METHODS OF FABRICATING THE SAME

(71) Applicant: Semprius, Inc., Durham, NC (US)

(72) Inventors: Steven Seel, Cary, NC (US); Etienne Menard, Durham, NC (US); David Kneeburg, Durham, NC (US); Baron Kendrick, Cary, NC (US); Bruce Furman, Plattsburgh, NY (US); Wolfgang Wagner, Chapel Hill, NC (US); Ray Jasinski, Chapel Hill, NC (US); Scott Burroughs, Raleigh, NC (US)

(21) Appl. No.: 13/705,980

(22) Filed: Dec. 5, 2012

Related U.S. Application Data
(60) Provisional application No. 61/568,900, filed on Dec. 9, 2011.

(51) Int. Cl. H01L 31/052; H01L 31/18

(52) U.S. Cl. CPC H01L 31/0524; H01L 31/18
USPC 136/246; 438/65

(57) ABSTRACT

A concentrator-type photovoltaic module includes a module enclosure having a rigid surface, and a flexible backplane within the enclosure and laminated to the rigid surface by an adhesive layer. The flexible backplane includes an array of interposer substrates having transfer-printed solar cells thereon and an interconnect network that provides electrical connections to the solar cells. A respective secondary spherical lens element is provided on respective ones of the solar cells within the enclosure. An optically transparent encapsulation layer may be provided on the secondary lens element of the respective ones of the solar cells, such that the secondary lens element including the encapsulation layer thereon has a different refractive index. A primary lens element is attached to the enclosure opposite to and spaced-apart from the rigid surface, and is positioned to concentrate light onto the respective ones of the solar cells through the secondary lens element thereon.

### CLAIM OF PRIORITY

This application claims priority from U.S. Provisional Patent Application No. 61/568,900, filed with the United States Patent and Trademark Office on Dec. 9, 2011, the disclosure of which is incorporated by reference herein in its entirety.

### STATEMENT OF GOVERNMENT INTEREST

This invention was made in cooperation with the U.S. Department of Energy under Contract No. NAT-0-99013-01. The U.S. government has certain rights in this invention.

### FIELD OF THE INVENTION

The invention is in the field of photovoltaics. More specifically the invention is in the field of high concentration photovoltaic module design and fabrication.

### BACKGROUND OF THE INVENTION

With the increasing demand for “green” solar power solutions in the global marketplace, cost reduction, manufacturing optimization, end-product reliability, high solar concentration, and performance efficiency have become targets of new solar module array designs and their fabrication. Related targets for high concentration photovoltaic modules may include lower cost backplanes and/or lower overall cost. Other solutions may also be used to achieve low cost secondary high index optics, which can be important for achieving very high concentration of sunlight onto micro-cell photovoltaic solar cells. Further goals include designs and methods for combining and interconnecting the solar array modules and affixing the solar module arrays and their enclosures onto solar tracking systems.

Flexible backplanes, lamination and unibody enclosures are described, for example, in U.S. Pat. No. 7,638,708 titled “Laminated Solar Concentrating Photovoltaic Device,” U.S. Pat. No. 6,399,874 titled “Solar Energy Module And Fresnel Lens For Use In Same,” U.S. Patent Application Publication No. 2009/0223555 titled “High Efficiency Concentrating Photovoltaic Module Method and Apparatus” and U.S. Patent Application Publication No. 2010/0282288 titled “Solar Cell Interconnection On A Flexible Substrate.” Silicone encapsulation for concentrator photovoltaics is described, for example, in U.S. Patent Application Publication No. 2010/0313954 titled “Concentrated Photovoltaic System Receiver for III-V Semiconductor Solar Cells,” U.S. Patent Application Publication No. 2011/0048535 titled “Encapsulated Concentrated Photovoltaic System Subassembly for III-V Semiconductor Solar Cells,” U.S. Patent Application Publication No. 2010/0065120 titled “Encapsulant With Modified Refractive Index”, and U.S. Patent Application Publication No. 2010/0319773 titled “Optics For Concentrated Photovoltaic Cell.” Spherical glass secondary concentrator photovoltaics are described, for example, in U.S. Patent Application Publication No. 2010/0236603 titled “Concentrator-Type Photovoltaic (CPV) Modules, Receiver and Sub-Receivers and Methods of Forming Same.” Photovoltaic module bonding to rails for optical and thermal performance is described, for example, in U.S. Pat. No. 7,868,244 titled “Solar CPV Cell Module And Method Of Safely Assembling, Installing, And/Or Maintaining The Same,” and in U.S. Patent Application Publication No. 2009/0261802 titled “Simulator System And Method For Measuring Acceptance Angle Characteristics Of A Solar Concentrator.”

### SUMMARY OF THE INVENTION

Solutions for realizing high efficiency solar modules may employ enclosures with low cost backplanes and low cost secondary high index optics to provide very high concentration of sunlight onto micro-cell photovoltaic solar cells, as well as designs and methods for combining and interconnecting solar array module elements and affixing solar arrays and their enclosures onto solar tracking systems. The use of micro-cells allows for the deployment of a large number of photovoltaic cells within each module, which may increase the overall efficiency and reliability of the photovoltaic modules.

In summary, some embodiments of the invention provide a high concentration photovoltaic (HCPV) module that includes a backplane comprising a patterned circuit on a dielectric substrate. The backplane provides electrical interconnection of a hybrid circuit including a plurality or multitude of solar cell receivers in a parallel-series wiring configuration in the enclosure, with a single reverse bias protection diode protecting each parallel bock comprising multiple solar cells, thus saving costs. The patterned circuit could be an etched layout of electrodeposited or rolled annealed copper with an anti-tarnish coating; a screen- or stencil-printed conductive ink made from graphite, copper, silver; a laminated, glued, or otherwise adhesive-bonded metal tape layup; or a slitted copper sheet provided by a roll-to-roll lamination approach. The dielectric substrate can be FR4, epoxy-impregnated glass fiber mat, polyimide, polyester, and/or some other printed circuit board dielectric material. The substrate can be thick enough to be free-standing without edge supports (0.063″ thickness typical), or as thin as 0.001″ as in a flexible circuit. The very thin substrates can reduce material utilization and decrease the thermal resistance. The substrates can be produced using low-cost high-volume roll-to-roll circuit fabrication methods. The solar cell(s) and diode(s) could be electrically connected to the patterned circuit though a solder reflow process, laser melting of eutectic solder, or using a metal-filled epoxy.

Some embodiments of the invention further include a module housing or enclosure, such as a unibody enclosure. The unibody enclosure provides a closed-bottom rigid frame, to which the backplane including the interconnected array of supported multijunction solar cells, a primary optical element, a junction box, and rails for mounting the module onto the tracker frame are attached. The unibody module enclosure may have the form of a deep tray that can be fabricated using a deep-draw metal stamping process, seam welding of a roll-formed or break-formed metal enclosure, or metal casting in a monolithic mold. All the aforementioned fabrication methods can create an enclosure with closed-bottom geometry. The module enclosure can also be fabricated from plastic or composite material using a sheet-molding compound, thermoset, or thermoplastic injection molding. As a variant, the enclosure can be composite, with overmolded plastic sidewalls over a metal bottom insert.

In some embodiments, the backplane is laminated into the module housing or enclosure. For example, the backplane lamination may be performed after surface mount technology (SMT) attachment of solar cells and diodes to the backplane, such that the lamination is performed with a circuit that is populated with components. For lamination of the backplane into the module enclosure an adhesive can be used, such as a single or dual-component epoxy, polyurethane, acrylic, and/or silicone-based adhesive. Depending on the choice, the adhesive can be cured at room temperature, and/or with a heat source or the addition of humidity or UV to promote curing. Additionally or alternatively, the adhesive can be a pressure sensitive adhesive or acrylic or silicone in tape form or sprayed as a hot melt. The lamination of the backplane can be accomplished using vacuum lamination in a diaphragm or platen press, using a hot-roll lamination press, and/or using an appropriate pressure distribution to improve contact to the adhesive and to reduce or minimize trapped air pockets. A series of small vent holes can also be added to the backplane to reduce the likelihood of trapping large voids at the adhesive interface. Alignment of the backplane to the module enclosure can be accomplished using mechanical references such as alignment pins or stamped/molded features in the module enclosure. Additionally or alternatively, alignment can be accomplished using optical pattern recognition through locating fiducials on the backplane and enclosure.

Some embodiments of the invention further include a secondary lens element, such as a spherical glass bead attached with silicone. In particular, the silicone may be an encapsulant layer used to attach and overcoat the spherical glass secondary lens element to the individual solar cells. The silicone overcoating can be carried out prior to attaching a primary lens element to the module. Also, an optically clear silicone layer can be positioned between the solar cell and the spherical glass secondary lens element to provide mechanical attachment of the secondary lens element, reduce reflection losses by improving index matching, and/or improve reliability by encapsulating the III-V solar cell. The silicone can be dispensed using needle dispense, spray coating, swirl coating, flood filling, curtain coating, gap coating, metering rod coating, slot die coating, dip coating, and/or air-knife coating. The silicone can be an addition-cure or neutral-cure system, which includes metal-catalyzed cure, moisture cure, peroxide cure, oxime-based, acid cure, or UV cure systems. The process for the attachment can include a bead drop with silicone attach, whereby the bead drop can be performed by placing the spherical glass secondary lens element above the solar cell prior to the silicone curing. The bead drop can be accomplished using end-of-arm tooling to accurately place one bead at a time onto an individual solar cell. Alternately, the bead drop can be realized in a massively parallel fashion using a trap-door stencil to drop an array of beads onto a multitude of solar cells in a single operation. The silicone overcoating after the bead drop may use similar dispense techniques and/or silicone materials as used for the underfill. The overcoat can act as a thick-film antireflection coating, and may allow for the use of a secondary lens element with a lower surface quality by smoothing out surface roughness, defects, and/or other imperfections in the secondary lens surface.

Some embodiments of the invention further include a junction box with a through-board connector that provides a path for the wiring from the backplane contacts to a set of solar connectors. The backplane includes a through-board connector that can be a bottom-entry connector, header pin receptacle, test-pin socket, or some other structure with which electrical connection can be made to the backplane. Additionally or alternatively, the backplane can have backside pads that are electrically contacted via direct soldering or ultrasonic bonding to junction box leads. The solar wiring and connectors may include components rated for photovoltaic use.

Some embodiments of the invention further include a primary lens element comprising refractive optics fabricated as planoconvex spherical or aspherical lenses, Fresnel lenses or multi-faceted lenses using materials such as acrylic (PMMA), silicone (PDMS), glass and co-molded products. In some embodiments, the primary lens element can be of either poly(methyl methacrylate) (abbreviated as PMMA), silicone on glass (piano-convex, Fresnel or faceted). As part of the massively parallel processing approach of embodiments of the invention, the primary lenses can be molded into a single array, such that only one alignment may be made to the multitude (hundreds) of receivers rather than a multitude of alignments (e.g., one alignment for each receiver). The primary lens can be attached to the unibody with a single continuous seal.

Other methods and/or devices according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF FIGURES

FIG. 1 is a partial cut view drawing of a HCPV module assembly depicting some embodiments of the present invention.

FIGS. 2a-2b illustrate methods for surface mounting CPV sub-receivers onto a flexible backplane according to some embodiments of the present invention.

FIG. 3 illustrates methods for laminating into a HCPV module enclosure a flexible backplane populated with an array of sub-receivers, according to some embodiments of the present invention.

FIGS. 4a-4b illustrate methods for attaching a spherical glass secondary lens onto a CPV sub-receiver according to some embodiments of the present invention.

FIGS. 5a-5b illustrate methods for over-coating and encapsulating a HCPV receiver assembly with an optically clear silicone layer according to some embodiments of the present invention.

FIG. 6 illustrates methods for attaching a primary lens array onto a unibody HCPV module enclosure with a single continuous seal according to some embodiments of the present invention.

FIG. 7 illustrates methods for attaching an array of HCPV modules to metal rails and junction boxes fitted with electrical harnesses, according to some embodiments of the present invention.

FIGS. 8a-8b illustrate methods for establishing electrical contacts to a backplane laminated inside a HCPV enclosure, and methods for sealing these electrical contacts in a potted junction box, according to embodiments of the present invention.

### DETAILED DESCRIPTION

Embodiments of the present invention provide solar array module enclosures that allow for the adhering of a flexible backplane (including an array of micro-solar cells thereon) into the bottom surface of a unibody enclosure, so as to employ lower cost material for a flexible backplane, realize high throughput, low-temperature, low-cost lamination, and provide a unibody module enclosure design with lower cost, fewer parts and improved reliability.

Embodiments of the invention also provide a silicone overcoated, high-index glass bead secondary optic for practical solar concentration, and allow the use of a lower quality glass bead secondary optic by employing the silicone overcoat to fill rough spots and defects in the surface of the glass bead, thereby altering (e.g., reducing or increasing) the refractive index. The adhesion of the glass bead is also improved, thereby improving the reliability of solar cells by encapsulating them with silicone. The silicone overcoat also acts as a thick-film anti-reflection coating on the glass bead.

Embodiments of the invention also allow for rail bonding of multiple flattened modules into arrays, whereby multiple modules can be placed onto a reference surface that allows for flattening of the bottom of the enclosure to ensure correct backplane-to-lens distance and coplanarity of the lens and backplane. Rail bonding to the backside of the enclosure further improves thermal performance by improving conduction and increasing the stiffness of the array structure.

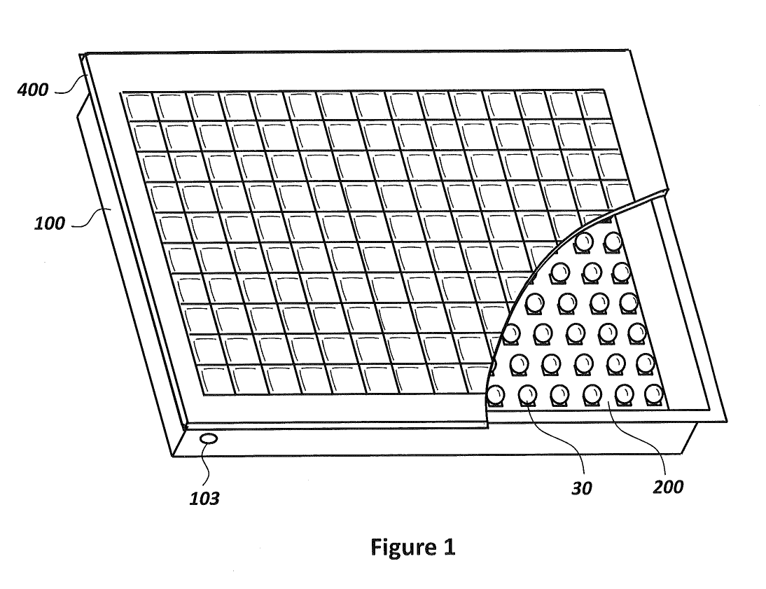

Some embodiments of the invention provide an HCPV module assembly as illustrated in FIG. 1. The HCPV module assembly includes the following components: an array of solar cell receivers (30), which are surface-mounted onto a flexible backplane (200), which is laminated into a closed bottom unibody enclosure (100), which is sealed with a primary lens array (400) and a liquid water proof breather membrane (103).

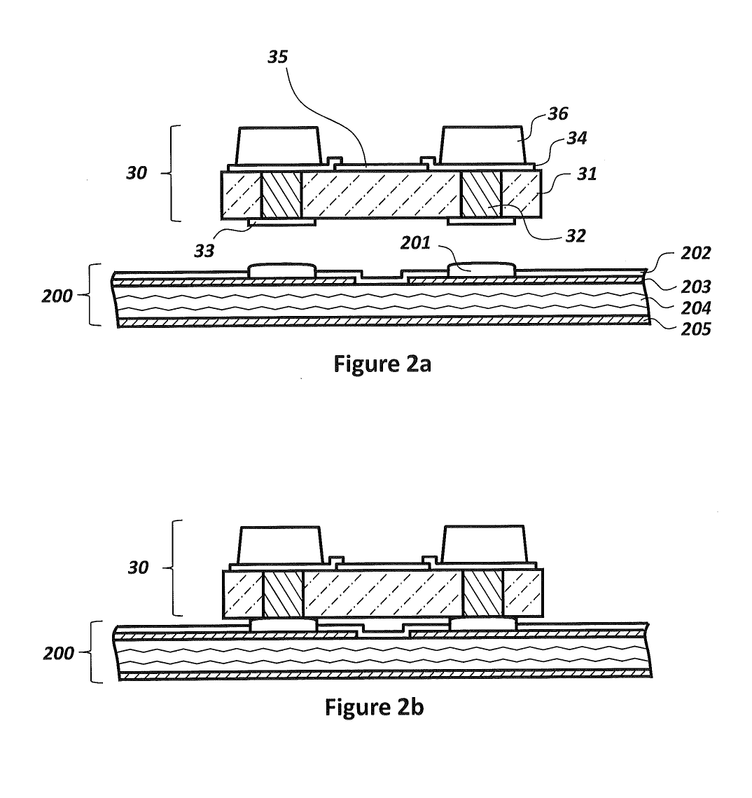

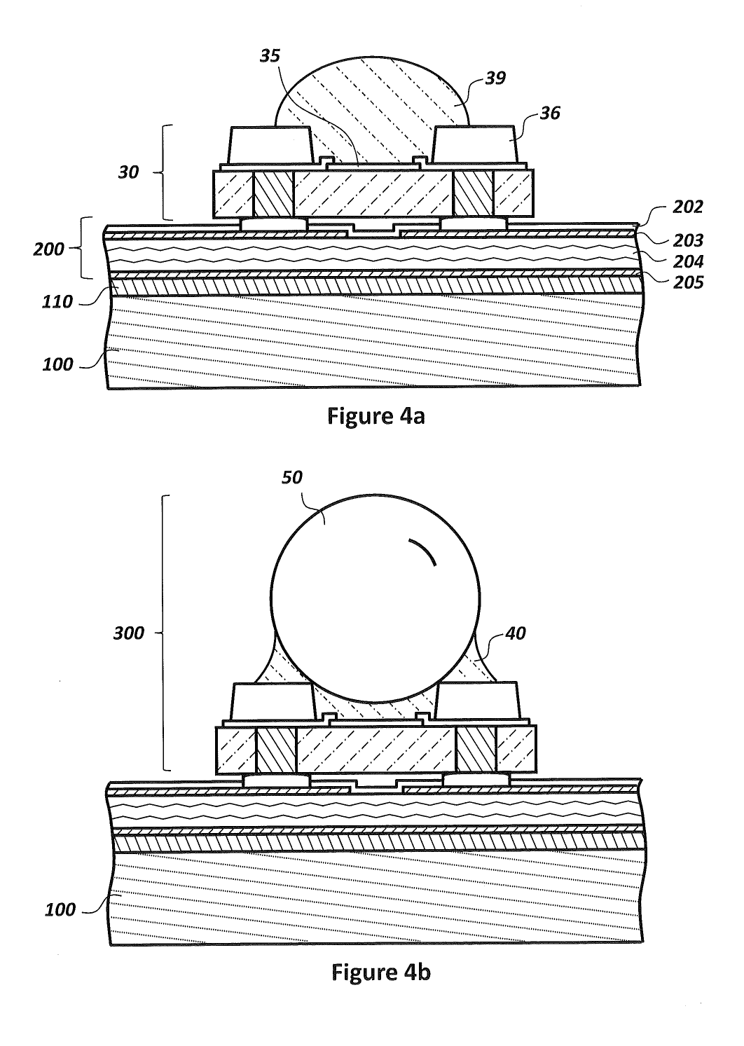

FIGS. 2a-2b illustrate a method for surface mounting CPV sub-receivers (30; generally referred to herein as a solar cell) onto a flexible backplane (200) according to some embodiments of the present invention. The surface mountable CPV sub-receiver (30) includes the following elements: an ultra-thin micro solar cell (35; also referred to herein as a thin-film photovoltaic layer) which can be micro-transfer printed onto to the upward-facing surface of a thermally conductive and electrically insulating interposer substrate (31); electrically conductive film interconnects (34) deposited on the upward-facing surface of the interposer substrate (31) that establish electrical connections to the solar cell (35); electrically conductive structures such as through vias (32) that establish electrical connection between the electrically conductive film interconnects (34) and contact pads (33) located on the downward-facing surface of the substrate (31); a spacer structure (36) which provides for both self aligning and supporting a spherically shaped secondary lens element (50; shown in FIG. 4b). In some embodiments of the invention, the flexible backplane (200) includes a printed wiring board, which may be composed of a fiber reinforced prepreg fiberglass composite dielectric layer (204) sandwiched between two copper clad laminates (203 & 205). The metal traces (203) defined on the upward-facing surface of the backplane (200) allow for interconnecting CPV sub-receivers in parallel and/or series strings. A dielectric layer (202) is deposited and patterned onto the upward-facing surface of the metal traces (203). Solder paste (201) may be deposited onto the dielectric layer openings using methods such as screen printing.

An array of CPV sub-receivers (30) and discrete bypass diodes are picked and placed onto the backplane (200). The assembled board is then heated in a reflow furnace to complete this surface mount assembly process as shown in FIG. 2b. In order to achieve distributed heat management with no heat sink, micro-cell based HCPV modules may rely on the use of a large number of sub-receiver parts. The number of bypass diodes used to protect the micro solar cells can be effectively reduced if multiple sub-receivers are interconnected in parallel blocks. In this embodiment, a single appropriately sized bypass diode may be used to protect multiple solar cells interconnected in each parallel block.

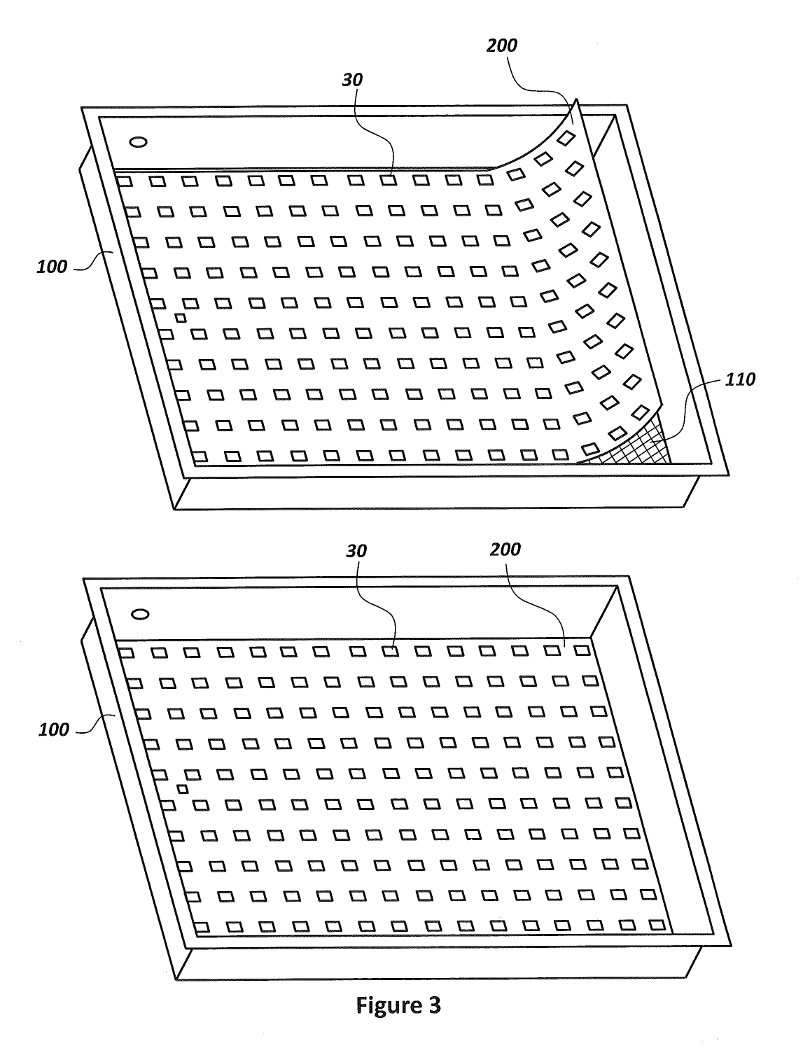

FIG. 3 illustrates a method for laminating a flexible backplane (200) populated with an array of sub-receivers (30) into a HCPV module enclosure (100). An adhesive layer (110) is dispensed or laminated directly onto the backside of the flexible backplane (200) (e.g., on a surface opposite the array of sub-receivers (30)) and/or directly on a rigid internal surface of the HCPV module enclosure (100). The adhesive may be chosen from the following list of materials: dual-component epoxy, polyurethane, acrylic, and/or silicone based adhesives. The backplane (200) is then laminated to the internal surface of the HCPV module enclosure (100) by the adhesive layer. In some embodiments of the invention, the lamination of the backplane (200) is accomplished using a vacuum lamination technique in a diaphragm or platen press or with a hot-roll lamination press.

FIGS. 4a-4b illustrate methods for attaching a spherical glass secondary lens element (50) onto a CPV sub-receiver (30) according to some embodiments of the present invention. In a first step, an optically clear silicone adhesive (39) is dispensed onto the upward facing surface of a sub-receiver (30) using liquid deposition methods such as needle dispense, spray coating, swirl coating, flood filling, curtain coating, gap coating, metering rod coating, slot die coating, dip coating, and/or air-knife coating. The spacer structure (36) defined on the upward facing surface of the sub-receiver provides for self aligning, centering, and supporting the spherically shaped secondary lens element. In some embodiments of the invention, a large array of spherical glass secondary lenses (50) may be dropped in a massively parallel manner using a trap-door stencil or a parallel plate fixture capable of holding and then dropping an array of spherical glass secondary lenses. The alignment accuracy of the bead drop tool may not be critical, as the final position of the spherical glass secondary lenses (50) can be ultimately defined by the position of spacer structures (36), insuring very accurate alignment of the spherical glass secondary lenses (50) to each micro solar cell (35). After completion of this bead drop process, the optically clear adhesive (39) may be partially or fully cured (40). This process step completes the formation of the full HCPV receiver assembly (300) which is then ready for an optional overcoat encapsulation process.

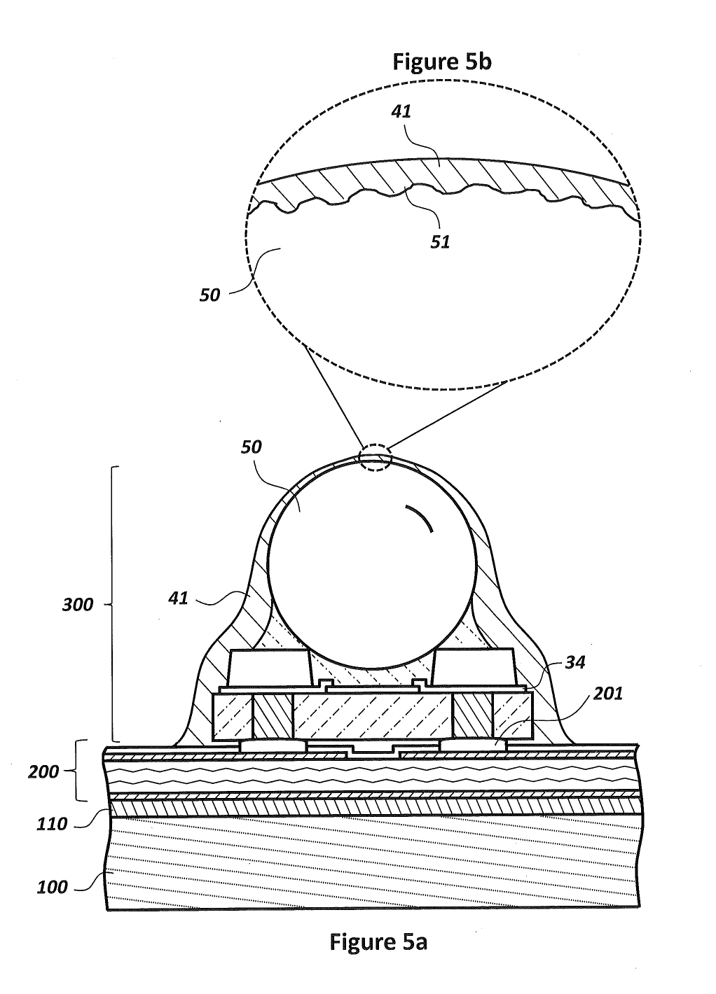

FIGS. 5a-5b illustrate methods for over-coating and encapsulating a HCPV receiver assembly (300) with an optically transparent encapsulant layer, such as a clear silicone layer (41). In particular, an optically clear silicone adhesive (41) is dispensed onto the top surface of a HCPV receiver assembly (300) using liquid deposition methods such as needle dispense, spray coating, swirl coating, flood filling, curtain coating, gap coating, metering rod coating, slot die coating, dip coating, and/or air-knife coating. As schematically illustrated in FIG. 5b, the thin silicone layer (41) provides for filling and/or smoothing surface defects or asperities (51) which may be present on the surface of the spherical glass secondary lenses (51). The thin silicone layer (41) also encapsulates the sub-receiver thin film interconnects (34) and solder joints (201).

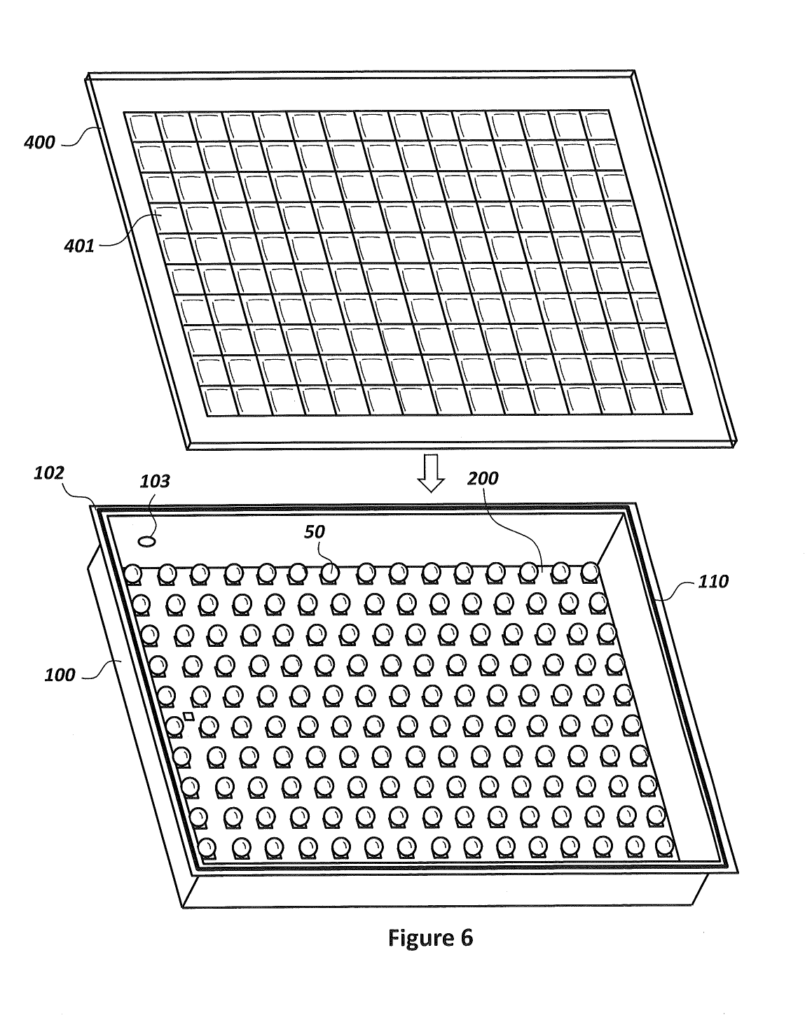

FIG. 6 illustrates methods for attaching a primary lens element (400) including an array of lenslets (401) onto a unibody HCPV module enclosure (100) with a single continuous seal (110). In particular embodiments of the invention, an array of plano-convex, Fresnel or faceted lenslets (401) are molded onto the downward facing surface of a glass plate. These lenslets may be made out of Poly (methyl methacrylate) abbreviated as PMMA or silicone. In some embodiments of the invention, a continuous sealing layer or sealant (110) is first dispensed onto the upward facing perimeter surface of the enclosure flange (102), and/or the downward facing perimeter of the primary lens array. The primary lens element (400) is then aligned to the array of CPV receiver assemblies (300) and sealed to the HCPV enclosure (100). A breather membrane (103) is also attached to the enclosure, which completes the assembly of the HCPV module.

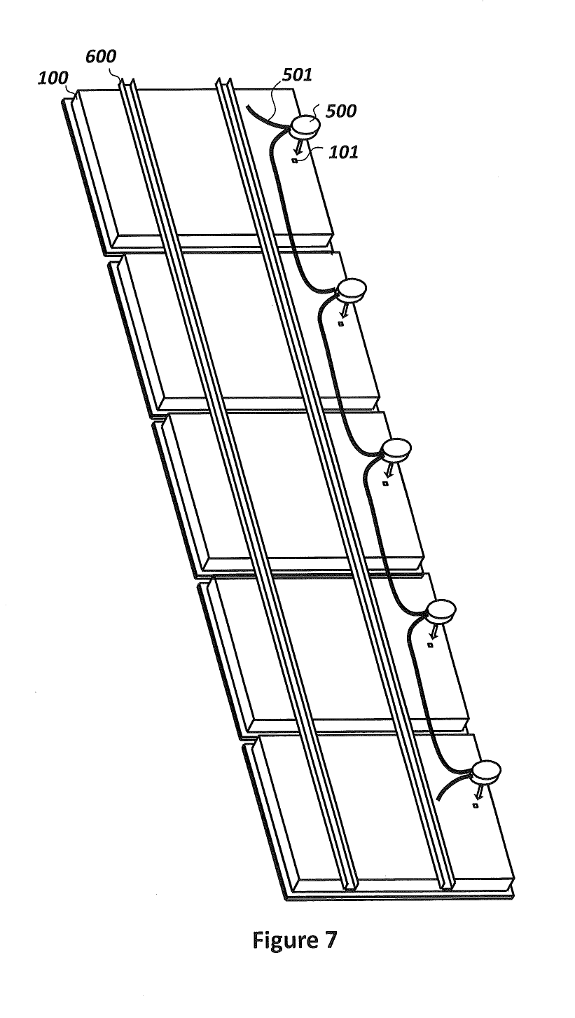

FIG. 7 illustrates methods for attaching metal rails (600) and junction boxes (500) fitted with an electrical harness (501) to an array of HCPV modules (100). In some embodiments of the invention, the HCPV module enclosures (100) are temporally pulled flat against a reference surface in order to insure co-planarity between the different modules. Metal rails (600) are then bonded to the co-planar HCPV modules (100) using a structural adhesive. The adhesive bond line thickness can be accurately controlled. In further embodiments of the invention, mechanically fasteners such as metal studs can be used as an alternate or complementary method to attach the HCPV module enclosures (100). These mechanical fasteners can provide an electrical ground path between the HCPV module enclosure (100) and the metal rails (600). Mechanical fasteners can also provide for holding an array of HCPV module enclosures (100) in mechanical contact with a set of metal rails (600) while the structural adhesive is curing. In some embodiments of the invention, junction boxes (500) fitted with a pre-fabricated electrical harness (501) are attached to the HCPV modules (100). Electrical contacts are established to the backplane through openings (101) defined in the bottom surface of the HCPV module enclosure.

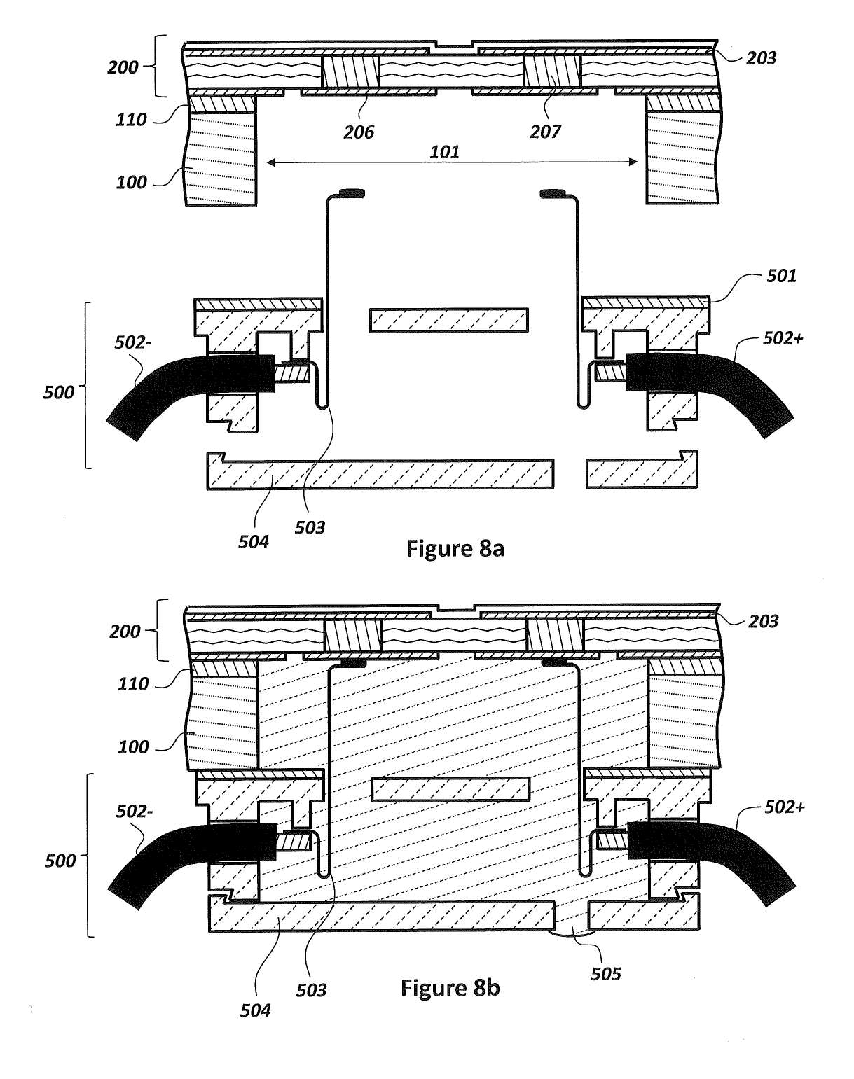

FIGS. 8a-8b illustrate exemplary methods of the invention for establishing electrical contacts from positive (502+) and negative (502−) external terminals or wires and contact pads (206) located on the bottom surface of a backplane (200) laminated inside a HCPV module enclosure (100). An opening (101) in the HCPV module enclosure (100) provides the clearance area to access the contact pads (206) from the bottom facing surface of the enclosure. In some embodiments of the invention, a junction box assembly (500) is attached to the bottom facing surface of the HCPV module enclosure (100) using an adhesive layer (501). Electrically conductive structures (503) such as metal pins or ribbons provide a mean for establishing electrical continuity between the positive (502+) and negative (502−) external wires and contact pads (206) located on the bottom surface of the backplane (200). In some embodiments of the invention, the electrically conductive structures (503) are welded to the contact pads (206) using a soldering robot. Through board vias (207) provides an electrical continuity path between the metal traces (203) defined on the upward-facing surface of the backplane (200) and the contact pads (206) located on the bottom surface of the backplane (200). In another embodiment of the invention, the positive (502+) and negative (502−) external wires may be soldered directly to the contact pads (206) located on the bottom surface of the backplane (200). In yet other embodiments of the invention, the backplane through board vias (207) may be replaced by a connector with through board pins thus providing another way for establishing electrical continuity between the metal traces (203) defined on the upward-facing surface of the backplane (200) and the contact pads (206) located on the bottom surface of the backplane (200). The junction box may be closed with a cap (504) and back-filled with potting compound (505).

The present invention has been described above with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the specification, there have been disclosed embodiments of the invention and, although specific terms are employed, they are used in a generic and descriptive sense only and not for purposes of limitation.

That which is claimed:

1. A concentrator-type photovoltaic module, comprising:
a module enclosure having a rigid surface;
a flexible backplane within the enclosure and laminated to the rigid surface by an adhesive layer, the flexible backplane comprising an array of interposer substrates including transfer-printed solar cells thereon and an interconnect network that provides electrical connections to the solar cells;
a respective secondary spherical lens element on respective ones of the solar cells within the enclosure; and
a primary lens element attached to the enclosure opposite to and spaced-apart from the rigid surface, wherein the primary lens is positioned to concentrate light onto the respective ones of the solar cells through the secondary lens element thereon.

2. The module of claim 1, further comprising:
an optically transparent encapsulant layer on a respective upward facing surface of the solar cells and on a surface of the respective secondary lens element thereon, wherein the surface of the respective secondary lens element including the encapsulant layer thereon has a different refractive index than that of the secondary lens element.

3. The module of claim 2, wherein the respective secondary lens element includes one or more defects in the surface thereof, and wherein the encapsulant layer comprises a silicone layer that substantially fills the one or more defects to smooth the surface of the respective secondary lens element.

4. The module of claim 3, wherein the solar cells include a respective spacer structure on the respective upward facing surface thereof, and wherein the secondary lens element thereof is self-centered by the spacer structure.

5. The module of claim 4, wherein the module enclosure comprises a unibody frame having a closed-bottom geometry, wherein the rigid surface provides a bottom surface of the unibody frame, and wherein the flexible backplane is laminated directly to the rigid surface by the adhesive layer.

6. The module of claim 5, further comprising:
a thermally conductive rail structure attached to the rigid surface opposite the flexible backplane and outside of the enclosure, wherein the rail structure increases a flatness and/or stiffness of the rigid surface.

7. The module of claim 6, further comprising:
a junction box assembly attached to the rigid surface opposite the flexible backplane and outside of the enclosure, the junction assembly comprising electrically conductive structures that extend through an opening in the rigid surface to contact the interconnect network of the flexible backplane and provide electrical connections between the solar cells and one or more external terminals.

8. The module of claim 5, wherein the solar cells respectively comprise a thermally conductive and electrically insulating interposer substrate that is surface-mounted to the flexible backplane and a thin film photovoltaic layer that is transfer-printed on the interposer substrate.

9. The module of claim 8, wherein the primary lens element comprises an array of lenslets attached to the unibody frame by a continuous seal extending along a perimeter of the unibody frame.

10. The module of claim 9, wherein the flexible backplane has a thickness of about 0.063 inches or less, wherein the one or more solar cells have respective surface areas of less than 1 square millimeter, and wherein the lenslets of the primary lens element respectively provide a lens-to-cell light concentration of about 1000 times or more.

11. The module of claim 1, wherein the interconnect network electrically connects the solar cells in parallel blocks, wherein a respective reverse-bias protection diode on the flexible backplane is connected in parallel with each parallel block of solar cells.

12. A method of fabricating a concentrator-type photovoltaic module, the method comprising:
laminating a flexible backplane to an internal rigid surface of a module enclosure using an adhesive layer, the flexible backplane comprising an array of interposer substrates including transfer-printed solar cells thereon and an interconnect network that provides electrical connections to the solar cells;
providing a respective spherical secondary lens element on respective ones of the solar cells within the enclosure;
depositing an optically transparent encapsulation layer on the secondary lens element of the respective ones of the solar cells, wherein the secondary lens element including the encapsulation layer thereon has a different refractive index than that of the secondary lens element; and
attaching a primary lens element to the enclosure opposite to and spaced-apart from the rigid surface, wherein the primary lens element is positioned to concentrate light onto the respective ones of the solar cells through the secondary lens element thereon.

13. The method of claim 12, wherein providing the secondary lens element on the respective ones of the solar cells comprises:
dispensing a transparent adhesive on the respective ones of the solar cells opposite the backplane; and
providing the spherical secondary lens element on the transparent adhesive on the respective ones of the solar cells, wherein the secondary lens element includes one or more defects in a surface thereof,
and wherein depositing the optically transparent encapsulation layer comprises:
depositing the optically transparent encapsulation layer to substantially fill the one or more defects to smooth the surface of the secondary lens element of the respective ones of the solar cells.

14. The method of claim 13, wherein the solar cells include a respective spacer structure on a surface thereof, and wherein the secondary lens element is self-centered by the spacer structure.

15. The method of claim 14, wherein the module enclosure comprises a unibody frame having a closed-bottom geometry, wherein the rigid surface defines a bottom surface of the unibody frame, and wherein the flexible backplane is laminated directly to the rigid surface by the adhesive layer.

16. The method of claim 15, further comprising:
transfer-printing a thin film photovoltaic layer on a surface of a thermally conductive and electrically insulating interposer substrate to define the respective solar cells; and
surface-mounting the interposer substrates to the flexible backplane to define the array of solar cells prior to laminating the flexible backplane to the rigid surface of the module enclosure.

17. The method of claim 16, wherein laminating the flexible backplane comprises:
depositing the adhesive layer on a surface of the flexible backplane opposite the one or more solar cells and/or on the rigid surface of the enclosure;
aligning the flexible backplane with a reference indicator on the rigid surface; and
bonding the flexible backplane to the rigid surface with the adhesive layer using a vacuum lamination process, hot-roll lamination process, or substantially even pressure distribution.

18. The method of claim 15, wherein the primary lens element comprises an array of lenslets, and wherein attaching the primary lens element comprises:
providing a continuous sealing layer along a perimeter of the unibody frame and/or the primary lens element;
aligning the primary lens element with the solar cells on the rigid surface such that the lenslets are positioned to concentrate light onto respective ones of the solar cells through the respective secondary lens element thereon; and
contacting the primary lens element with the perimeter of the unibody frame such that the sealing layer provides a continuous seal along the perimeter.

19. The method of claim 15, further comprising:
pulling the rigid surface against a substantially planar reference surface; and then
attaching a thermally conductive rail structure to the rigid surface opposite the flexible backplane and outside of the enclosure, wherein the rail structure increases a flatness and/or stiffness of the rigid surface.

20. The method of claim 19, further comprising:
attaching a junction box assembly to the rigid surface opposite the flexible backplane and outside of the enclosure, the junction box assembly comprising electrically conductive structures that extend through an opening in the rigid surface to contact the interconnect network of the flexible backplane and provide electrical connections between the solar cells and one or more external terminals.

21. A process for fabricating a concentrator-type photovoltaic module, the process comprising the steps of:
(a) laminating a flexible backplane to a rigid internal surface of a unibody module enclosure using an adhesive layer, the flexible backplane comprising an array of interposer substrates including transfer-printed solar cells thereon and an interconnect network that provides electrical connections to the solar cells;
(b) providing a respective secondary lens element on respective ones of the solar cells within the enclosure;
(c) depositing an optically transparent encapsulation layer on the secondary lens element of the respective ones of the solar cells, wherein the secondary lens element including the encapsulation layer thereon has an altered refractive index relative to that of the secondary lens element alone;
(d) attaching a primary lens element to the enclosure opposite to and spaced-apart from the rigid surface, wherein the primary lens element is positioned to concentrate light onto the respective ones of the solar cells through the secondary lens element thereon;
(e) attaching a thermally conductive rail structure to the rigid surface of the module enclosure opposite the flexible backplane, wherein the rail structure increases a flatness and/or stiffness of the rigid surface; and
(f) attaching a junction box assembly to the rigid surface of the module enclosure opposite the flexible backplane, the junction assembly comprising electrically conductive structures that extend through an opening in the rigid surface to contact the interconnect network of the flexible backplane and provide electrical connections to external terminals.

22. The process of claim 21, wherein the step (b) of providing the respective secondary lens element on respective ones of the solar cells comprises:
dispensing a transparent adhesive on the respective ones of the solar cells opposite the backplane; and
providing the secondary lens element on the transparent adhesive on the respective ones of the solar cells, wherein the secondary lens element includes one or more defects in a surface thereof,
and wherein depositing the optically transparent encapsulation layer comprises:
depositing the optically transparent encapsulation layer to substantially fill the one or more defects to smooth the surface of the secondary lens element on the respective ones of the solar cells.

23. The process of claim 22, wherein the step (a) of laminating the flexible backplane comprises:
depositing the adhesive layer on a surface of the flexible backplane opposite the one or more solar cells and/or on the rigid surface of the enclosure;
aligning the flexible backplane with a reference indicator on the rigid surface; and
bonding the flexible backplane to the rigid surface with the adhesive layer using a vacuum lamination process, hot-roll lamination process, or substantially even pressure distribution.
